(19) United States
(12) Patent Application Publication
(10) Pub. No.: US 2025/0076843 A1
(43) Pub. Date: Mar. 6, 2025

(54) INFORMATION PROCESSING APPARATUS, INFORMATION PROCESSING METHOD, AND SEMICONDUCTOR MANUFACTURING SYSTEM

(71) Applicant: Tokyo Electron Limited, Tokyo (JP)

(72) Inventors: Masakazu YAMAMOTO, Iwate (JP); Tadashi ENOMOTO, Iwate (JP)

(21) Appl. No.: 18/812,476

(22) Filed: Aug. 22, 2024

(30) Foreign Application Priority Data
Sep. 1, 2023 (JP) 2023-142068

(51) Int. Cl. G05B 19/4065; G05B 19/404; G05B 19/4069; G05B 19/408

(52) U.S. Cl. CPC G05B 19/4065; G05B 19/404; H01L 21/67242; G05B 2219/37214; G05B 2219/45031; G05B 2219/45045

(57) ABSTRACT

An information processing apparatus executes a simulation of a process state, which is being executed in a semiconductor manufacturing apparatus using a physical model of the semiconductor manufacturing apparatus. The information processing apparatus includes a simulation execution unit that executes the simulation by setting operating conditions of the physical model to the same conditions as those of the semiconductor manufacturing apparatus; a physical coefficient change unit that changes a physical coefficient of the physical model such that an output value of the physical model approximates to a corresponding output value of the semiconductor manufacturing apparatus a deterioration state analysis unit that analyzes a deterioration state of the semiconductor manufacturing apparatus, based on a change in the physical coefficient; and a deterioration state output unit that outputs information regarding the deterioration state of the semiconductor manufacturing apparatus, analyzed by the deterioration state analysis unit.

### CROSS-REFERENCE TO RELATED APPLICATIONS

This application is based on and claims priority from Japanese Patent Application No. 2023-142068 filed on Sep. 1, 2023 with the Japan Patent Office, the disclosure of which is incorporated herein in its entirety by reference.

### TECHNICAL FIELD

The present disclosure relates to an information processing apparatus, an information processing method, and a semiconductor manufacturing system.

### BACKGROUND

In the field of the manufacture, or research and development of semiconductor products, a process simulation is utilized. In the process simulation, various physical phenomena related to a semiconductor process (hereinafter, referred to as a process) may be handled by a physical model (see, e.g., Japanese Patent Laid-Open Publication No. 2018-125451).

For example, in the process simulation, a process state where a process was being executed (e.g., a wafer film attachment method, a temperature state, and a gas state) is estimated based on a measurement result which has been obtained after executing the process.

### SUMMARY

According to an aspect of the present disclosure, an information processing apparatus executes a simulation of a process state, which is being executed in a semiconductor manufacturing apparatus, using a physical model of the semiconductor manufacturing apparatus. The information processing apparatus includes a simulation execution unit that executes the simulation by setting operating conditions of the physical model to the same conditions as those of the semiconductor manufacturing apparatus; a physical coefficient change unit that changes a physical coefficient of the physical model such that an output value of the physical model approximates to a corresponding output value of the semiconductor manufacturing apparatus; a deterioration state analysis unit that analyzes a deterioration state of the semiconductor manufacturing apparatus, based on a change in the physical coefficient; and a deterioration state output unit that outputs information regarding the deterioration state of the semiconductor manufacturing apparatus analyzed by the deterioration state analysis unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram of a semiconductor manufacturing system according to an embodiment of the present disclosure.

FIG. 2 is a hardware configuration diagram of a computer.

FIG. 3 is a functional block diagram of an autonomous control controller according to the embodiment.

FIG. 4 is a flowchart illustrating data assimilation in the semiconductor manufacturing system according to the embodiment.

FIG. 5 is a flowchart illustrating deterioration state analysis of the semiconductor manufacturing system according to the embodiment.

FIG. 6 is a flowchart illustrating prediction of the semiconductor manufacturing system according to the embodiment.

FIG. 7 is a flowchart illustrating process parameter adjustment of the semiconductor manufacturing system according to the embodiment.

FIG. 8 is a flowchart illustrating optimization for each cleaning process of the semiconductor manufacturing system according to the embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings. In the respective drawings, the same components may be denoted by the same reference numerals, and overlapping descriptions thereof may be omitted.

### <System Configuration>

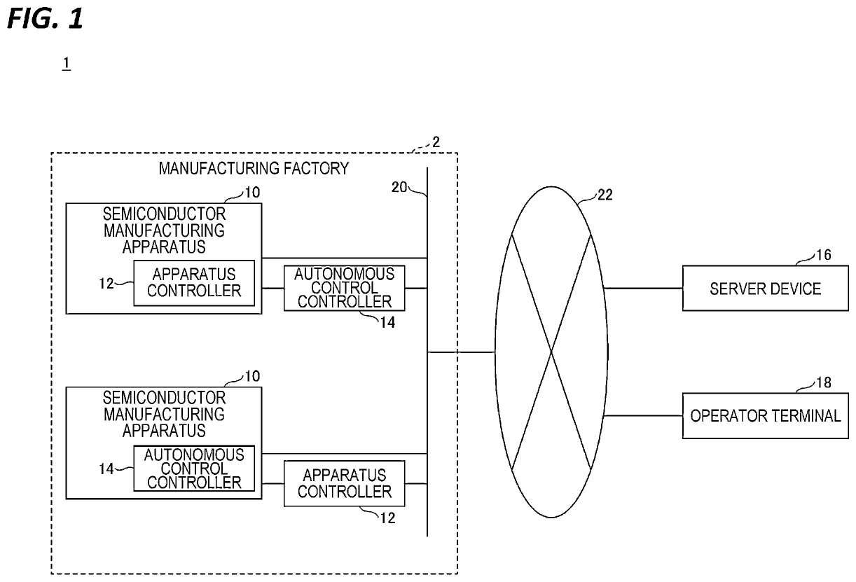

FIG. 1 is a configuration diagram of a semiconductor manufacturing system 1 according to an embodiment of the present disclosure. The semiconductor manufacturing system 1 illustrated in FIG. 1 includes a semiconductor manufacturing apparatus 10, an apparatus controller 12, an autonomous control controller 14, a server device 16, and an operator terminal 18.

The semiconductor manufacturing apparatus 10, the apparatus controller 12, and the autonomous control controller 14 are installed in a manufacturing factory 2. The server device 16 and the operator terminal 18 may be installed in the manufacturing factory 2 or may be installed outside the manufacturing factory 2. The operator terminal 18 is an information processing terminal operated by an operator, such as an apparatus manager or an analyzer of the semiconductor manufacturing apparatus 10 installed in the manufacturing factory 2. The semiconductor manufacturing apparatus 10, the apparatus controller 12, the autonomous control controller 14, the server device 16, and the operator terminal 18 are communicatively connected to networks 20 and 22 such as the Internet or local area network (LAN).

The semiconductor manufacturing apparatus 10 is an apparatus that performs a processing, such as a film forming processing, an etching processing, or an ashing processing, and processes, for example, a semiconductor wafer (hereinafter, simply referred to as a wafer). The semiconductor manufacturing apparatus 10 is, for example, a substrate processing apparatus, a heat treatment apparatus, or a film forming apparatus.

The semiconductor manufacturing apparatus 10 receives, for example, control instructions (process parameters) according to a recipe, from the apparatus controller 12, and executes a process. The semiconductor manufacturing apparatus 10 is equipped with a plurality of sensors such as a temperature sensor that measures a temperature and a pressure sensor that measures a pressure, to monitor a process state.

The apparatus controller 12 has a function of a man-machine interface that receives instructions for the semiconductor manufacturing apparatus 10 from an operator and provides information regarding the semiconductor manufacturing apparatus 10 to the operator. The apparatus controller 12 receives output values (an example of output values of the semiconductor manufacturing apparatus 10), such as sensor values output from a plurality of sensors installed in the semiconductor manufacturing apparatus 10. In addition, the apparatus controller 12 is an information processing apparatus that executes a simulation of the process state, which is being executed in the semiconductor manufacturing apparatus 10 using a physical model of the semiconductor manufacturing apparatus 10. The apparatus controller 12 illustrated in FIG. 1 is installed in each semiconductor manufacturing apparatus 10, but may be installed in each of a plurality of semiconductor manufacturing apparatuses 10. The apparatus controller 12 may be installed within a housing of the semiconductor manufacturing apparatus 10 or may be installed outside the housing.

The autonomous control controller 14 is a controller for autonomously controlling the semiconductor manufacturing apparatus 10. The autonomous control controller 14 receives output values (an example of output values of the semiconductor manufacturing apparatus 10), such as sensor values output from a plurality of sensors installed in the semiconductor manufacturing apparatus 10. In addition, the autonomous control controller 14 is an information processing apparatus that executes a simulation of the process state, which is being executed in the semiconductor manufacturing apparatus 10 using the physical model of the semiconductor manufacturing apparatus 10. The autonomous control controller 14 optimizes process parameters of the semiconductor manufacturing apparatus 10, predicts a timing and a content of failure of the semiconductor manufacturing apparatus 1, and predicts a timing and a content of maintenance of the semiconductor manufacturing apparatus 10.

The autonomous control controller 14 illustrated in FIG. 1 is installed in each semiconductor manufacturing apparatus 10, but may be installed in each of the plurality of semiconductor manufacturing apparatuses 10. The autonomous control controller 14 may be installed within the housing of the semiconductor manufacturing apparatus 10, or may be installed outside the housing.

The server device 16 receives output values (an example of output values of the semiconductor manufacturing apparatus 10), such as sensor values output from the plurality of sensors installed in the semiconductor manufacturing apparatus 10, and stores them as a process log. The server device 16 is an information processing apparatus that executes the simulation of the process state, which is being executed in the semiconductor manufacturing apparatus 10, using the physical model of the semiconductor manufacturing apparatus 10.

The server device 16 may store information (process parameters for executing a process on the semiconductor manufacturing apparatuses 10, sensor values for executing the process according to the process parameters, and process result data) regarding the plurality of semiconductor manufacturing apparatuses 10 of one or more manufacturing factories 2 as a process log. The process log of the plurality of semiconductor manufacturing apparatuses 10 may be used to improve the accuracy of the simulation of the process state, which is being executed in the semiconductor manufacturing apparatus 10.

The apparatus controller 12, the autonomous control controller 14, and the server device 16 may notify an operator of the operator terminal 18 of information regarding the semiconductor manufacturing apparatus 10, information regarding a result of the simulation, or information regarding a deterioration state of the semiconductor manufacturing apparatus 10, using e-mail.

The semiconductor manufacturing system 1 illustrated in FIG. 1 is provided by way of an example, and various examples of system configurations may be provided depending on usage or purposes. The classification of apparatuses such as the apparatus controller 12, the autonomous control controller 14, and the server device 16 illustrated in FIG. 1 is provided by way of an example. For example, the semiconductor manufacturing system 1 may have various configurations, such as a configuration in which at least two of the apparatus controller 12, the autonomous control controller 14, and the server device 16 are integrated, or a configuration in which they are further divided. In addition, the apparatus controller 12 and the autonomous control controller 14 may handle the plurality of semiconductor manufacturing apparatuses 10 in an integrated manner.

### <Hardware Configuration>

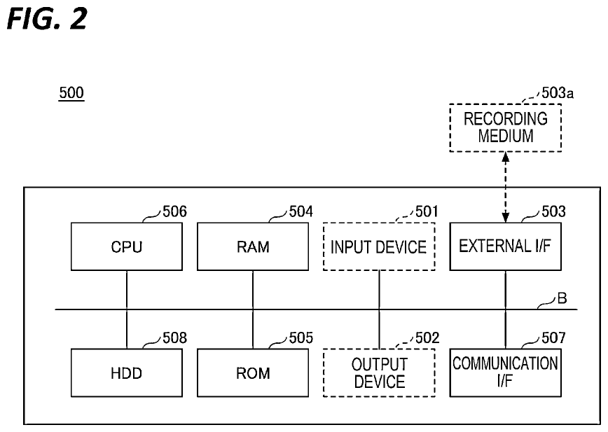

The apparatus controller 12, the autonomous control controller 14, the server device 16, and the operator terminal 18 of the semiconductor manufacturing system 1 illustrated in FIG. 1 are implemented by a computer with a hardware configuration illustrated in FIG. 2, for example. FIG. 2 is a hardware configuration diagram of a computer 500.

The computer 500 of FIG. 2 includes an input device 501, an output device 502, an external I/F (interface) 503, a random access memory (RAM) 504, a read only memory (ROM) 505, a central processing unit (CPU) 506, a communication I/F 507, and a hard disk drive (HDD) 508, each of which is connected by a bus B. The input device 501 and the output device 502 may be connected and used as needed.

The input device 501 is a keyboard, a mouse, or a touch panel and is used to input each operational signal by an operator. The output device 502 is a display and displays a result of a processing by the computer 500. The communication I/F 507 is an interface that connects the computer 500 to the networks 20 and 22 illustrated in FIG. 1. The HDD 508 is a non-volatile storage device that stores programs or data.

The external I/F 503 is an interface to an external device. The computer 500 may perform reading on a recording medium 503a, such as a secure digital (SD) memory card, via the external I/F 503. The external I/F 503 may perform recording on the recording medium 503a, such as an SD memory card, via the external I/F 503.

The ROM 505 is a non-volatile semiconductor memory (storage device) where programs and data are stored. The RAM 504 is a volatile semiconductor memory (storage device) that temporarily holds programs and data. The CPU 506 is a computing device that reads programs and data from the storage device such as the ROM 505 or the HDD 508 and executes a processing to implement control and functions of the entire computer 500.

The apparatus controller 12, the autonomous control controller 14, the server device 16, and the operator terminal 18 of the semiconductor manufacturing system 1 illustrated in FIG. 1 implement various functions by executing a program with the computer 500.

### <Functional Configuration>

Hereinafter, an example will be described where the information processing apparatus that executes a simulation of a process state, which is being executed in the semiconductor manufacturing apparatus 10, using the physical model of the semiconductor manufacturing apparatus 10, is the autonomous control controller 14. The information processing apparatus that executes the simulation of the process state, which is being executed in the semiconductor manufacturing apparatus 10, using the physical model of the semiconductor manufacturing apparatus 10, may be the apparatus controller 12 or the server device 16.

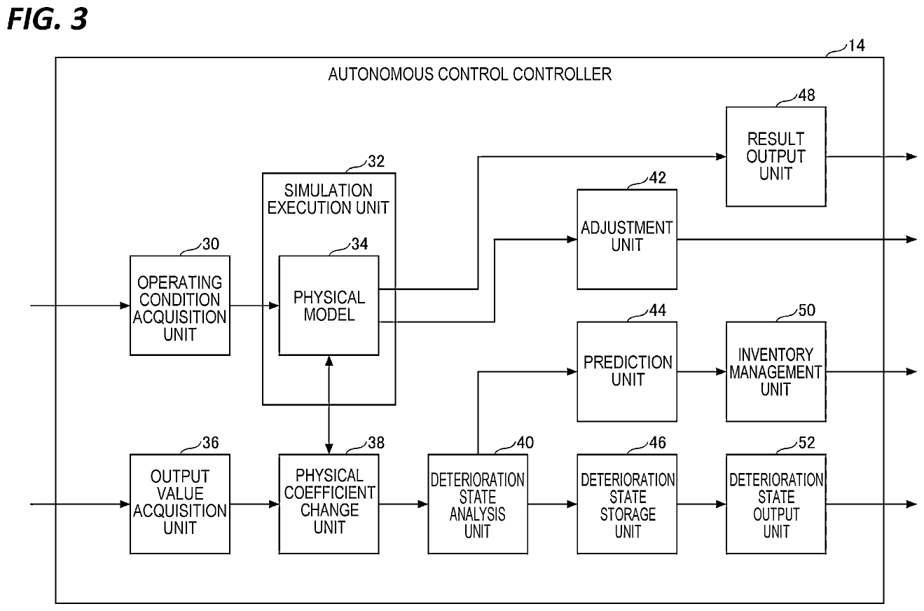

The autonomous control controller 14 of the semiconductor manufacturing system 1 according to the embodiment is implemented, for example, by functional blocks illustrated in FIG. 3. FIG. 3 is a functional block diagram of the autonomous control controller 14 according to the embodiment. The functional block diagram of FIG. 3 omits the illustration of components that are unnecessary for explanation of the embodiment.

The autonomous control controller 14 implements an operating condition acquisition unit 30, a simulation execution unit 32, a physical model 34, an output value acquisition unit 36, a physical coefficient change unit 38, a deterioration state analysis unit 40, an adjustment unit 42, a prediction unit 44, a deterioration state storage unit 46, a result output unit 48, an inventory management unit 50, and a deterioration state output unit 52 by executing a program for the autonomous control controller 14.

The operating condition acquisition unit 30 acquires the process parameters of the semiconductor manufacturing apparatus 10 executing a process as operating conditions. The output value acquisition unit 36 acquires output values such as a sensor value and a data value of the semiconductor manufacturing apparatus 10 when the semiconductor manufacturing apparatus 10 executes a process according to the process parameters acquired by the operating condition acquisition unit 30 as operating conditions.

The simulation execution unit 32 includes the physical model 34 of the semiconductor manufacturing apparatus 10, which executes a simulation. The physical model 34 is a model that utilizes the law of nature and is represented by a formula derived from natural science. For example, the physical model 34 is a thermal model that outputs a prediction temperature of Inner T/C in a processing container of the semiconductor manufacturing apparatus 10 according to heater power. For example, the thermal model of the semiconductor manufacturing apparatus 10 is generated based on information such as apparatus dimensions and physical property data of the semiconductor manufacturing apparatus 10. The relationship of heat exchanges, and specific heat are modeled in the thermal model. The simulation execution unit 32 includes the physical model 34 corresponding to the output value of the semiconductor manufacturing apparatus 10 acquired by the output value acquisition unit 36.

The simulation execution unit 32 sets operating conditions of the physical model 34 executing a simulation to the same conditions as operating conditions of the semiconductor manufacturing apparatus 10 and executes a simulation of the output value of the semiconductor manufacturing apparatus 10 using the physical model 34.

The physical coefficient change unit 38 changes a physical coefficient of the physical model 34 such that the simulated output value of the physical model 34 approximates to (may coincide with) the output value of the semiconductor manufacturing apparatus 10 acquired by the output value acquisition unit 36 (the output value of the semiconductor manufacturing apparatus 10 corresponding to the simulated output value of the physical model 34).

The physical coefficient change unit 38 performs data assimilation of the semiconductor manufacturing apparatus 10 and the physical model 34 by sequentially changing the physical coefficients of the physical model 34 such that the output value of the physical model 34 approximates to the output value of the semiconductor manufacturing apparatus 10 under the same operating conditions.

The deterioration state analysis unit 40 analyzes the deterioration state of the semiconductor manufacturing apparatus 10 based on a change in the physical coefficient of the physical model 34, which has been changed by the physical coefficient change unit 38. For example, the deterioration state analysis unit 40 may analyze that deterioration has progressed increasingly according to an increase in a difference between a physical coefficient of the physical model 34 at an initial stage and the changed physical coefficient of the physical model 34 if the physical model 34 at the initial stage is an ideal model. The deterioration state analysis unit 40 may analyze that the smaller difference between the physical coefficient of the physical model 34 at the initial stage and the changed physical coefficient of the physical model 34, the lesser deterioration is occurring. For example, if the physical coefficient of the physical model 34 in a temperature-transmissive portion of an insulator has changed, the deterioration state analysis unit 40 may analyze a possible deterioration of the insulator of the semiconductor manufacturing apparatus 10. The deterioration state analysis unit 40 may quantitatively analyze the deterioration state of the semiconductor manufacturing apparatus 10 and may also analyze characteristics of the deterioration state of the semiconductor manufacturing apparatus 10 for a predetermined period of operation.

The deterioration state analysis unit 40 may analyze the deterioration state of the semiconductor manufacturing apparatus 10 using a prediction model that has machine-learned a relationship between a change in one or more physical coefficients of the physical model 34 and the deterioration state of the semiconductor manufacturing apparatus 10. The machine learning of the prediction model may be performed by adjusting parameters of the prediction model to output the deterioration state of the semiconductor manufacturing apparatus 10 when the change in the one or more physical coefficients of the physical model 34 is input, using teaching data that correlates the change in the one or more physical coefficients of the physical model 34 with the deterioration state of the semiconductor manufacturing apparatus 10.

The deterioration state storage unit 46 stores information regarding the deterioration state of the semiconductor manufacturing apparatus 10, which is analyzed by the deterioration state analysis unit 40. The deterioration state output unit 52 outputs information regarding the deterioration state of the semiconductor manufacturing apparatus 10, which is analyzed by the deterioration state analysis unit 40. For example, the deterioration state output unit 52 may transmit the information regarding the deterioration state of the semiconductor manufacturing apparatus 10, analyzed by the deterioration state analysis unit 40, to the operator terminal 18, to notify the operator of the information. The deterioration state output unit 52 may also transmit the information regarding the deterioration state of the semiconductor manufacturing apparatus 10, analyzed by the deterioration state analysis unit 40, to the apparatus controller 12 to display the information on the apparatus controller 12.

The prediction unit 44 predicts a timing and a content of maintenance, which are required for the semiconductor manufacturing apparatus 10, based on the information regarding the deterioration state of the semiconductor manufacturing apparatus 10, analyzed by the deterioration state analysis unit 40. For example, the prediction unit 44 may predict the timing and the content of the maintenance required for the semiconductor manufacturing apparatus 10, based on a change in the deterioration state over time, of the semiconductor manufacturing apparatus 10, analyzed by the deterioration state analysis unit 40 (e.g., variation in the deterioration state for a predetermined period).

The inventory management unit 50 manages an inventory of parts required for the maintenance of which the timing and the content have been predicted by the prediction unit 44. For example, the inventory management unit 50 specifies the parts required for the maintenance of which the timing and the content have been predicted by the prediction unit 44, and manages the inventory such that the parts required at the timing of the maintenance are in inventory. The inventory management unit 50 may be associated with a purchasing system to automatically order parts to meet the timing of the maintenance.

The adjustment unit 42 may adjust process parameters of the operating conditions of the semiconductor manufacturing apparatus 10 to uniformize the quality of wafers manufactured by the semiconductor manufacturing apparatus 10, based on the result of the simulation of the process state, which is being executed in the semiconductor manufacturing apparatus 10 by the simulation execution unit 32. The adjustment unit 42 optimizes the process parameters of the operating conditions of the semiconductor manufacturing apparatus 10 based on the result of the simulation. The result output unit 48 outputs the result of the simulation of the process state, which has been executed in the semiconductor manufacturing apparatus 10 by the simulation execution unit 32.

As described above, the semiconductor manufacturing system 1 according to the embodiment may implement a digital twin that reproduces a change in a physical space, called a process state of the semiconductor manufacturing apparatus 10 executing a process, in a virtual space (cyber space) with real-time interoperability. The digital twin may reproduce the process state of the semiconductor manufacturing apparatus 10 in the virtual space in real time while executing a process in the semiconductor manufacturing apparatus 10. By utilizing the environment of the digital twin, the semiconductor manufacturing system 1 according to the embodiment may monitor the process state of the semiconductor manufacturing apparatus 10. In addition, the semiconductor manufacturing system 1 according to the embodiment may predict the timing and the content of failure of the semiconductor manufacturing apparatus 10, predict the timing and the content of maintenance of the semiconductor manufacturing apparatus 10, and adjust the process parameters of the semiconductor manufacturing apparatus 10.

### <Processings>

### <<Data Assimilation>>

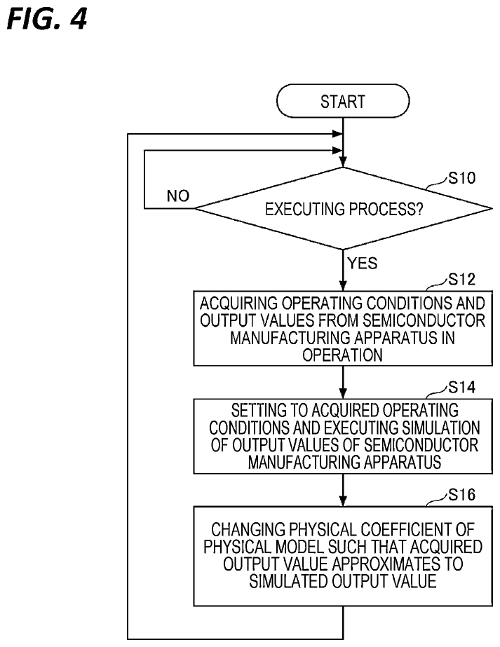

The semiconductor manufacturing system 1 according to the embodiment performs data assimilation, for example, as illustrated in FIG. 4, based on the operating conditions acquired by the operating condition acquisition unit 30 and the output values acquired by the output value acquisition unit 36 from the semiconductor manufacturing apparatus 10 in operation. FIG. 4 is a flowchart illustrating data assimilation in the semiconductor manufacturing system 1 according to the embodiment.

In step S10, the autonomous control controller 14 performs processings of steps S12 to S16 when the semiconductor manufacturing apparatus 10 executes a process.

In step S12, the operating condition acquisition unit 30 acquires process parameters as operating conditions from the semiconductor manufacturing apparatus 10 in operation, executing the process. The output value acquisition unit 36 acquires output values of the semiconductor manufacturing apparatus 10, such as a sensor value and a data value of the semiconductor manufacturing apparatus 10 executing the process, according to the process parameters acquired by the operating condition acquisition unit 30 as the operating conditions.

In step S14, the simulation execution unit 32 sets the operating conditions of the physical model 34 executing the simulation to the same conditions as the operating conditions of the semiconductor manufacturing apparatus 10 and executes the simulation of the output value of the semiconductor manufacturing apparatus 10 using the physical model 34.

In step S16, the physical coefficient change unit 38 changes the physical coefficient of the physical model 34 such that the simulated output value of the physical model 34 approximates to the output value of the semiconductor manufacturing apparatus 10 acquired by the output value acquisition unit 36. In this manner, the physical coefficient change unit 38 performs data assimilation of the semiconductor manufacturing apparatus 10 and the physical model 34 by sequentially changing the physical coefficients of the physical model 34 such that the output value of the physical model 34 approximates to the output value of the semiconductor manufacturing apparatus 10 under the same operating conditions. The sequentially changing the physical coefficients of the physical model 34 such that the output value of the physical model 34 approximates to the output value of the semiconductor manufacturing apparatus 10 includes tuning (adjusting) discrepancy between the semiconductor manufacturing apparatus 10 and the physical model 34 in operation.

By the processing of data assimilation of FIG. 4, the semiconductor manufacturing system 1 according to the embodiment may correct the physical model 34 such that the output value of the semiconductor manufacturing apparatus 10 in operation assimilates with the output value of the physical model 34 based on the operating conditions of the semiconductor manufacturing apparatus 10 in operation and the output value of the semiconductor manufacturing apparatus 10 executing the process according to the operating conditions.

### <<Deterioration State Analysis>>

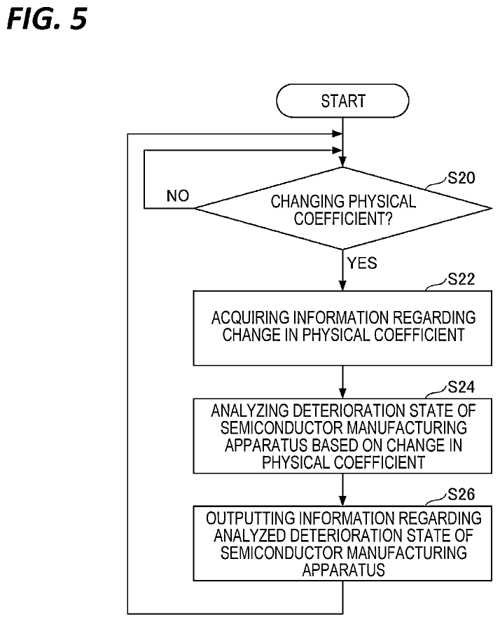

The semiconductor manufacturing system 1 according to the embodiment analyzes and outputs information regarding the deterioration state of the semiconductor manufacturing apparatus 10 in operation, for example, as illustrated in FIG. 5, based on the change in the physical coefficients of the physical model 34 changed by the data assimilation. FIG. 5 is a flowchart illustrating deterioration state analysis of the semiconductor manufacturing system 1 according to the embodiment.

In step S20, the autonomous control controller 14 performs processings of steps S22 to S26 when the physical coefficient of the physical model 34 is changed by the physical coefficient change unit 38.

In step S22, the deterioration state analysis unit 40 acquires information regarding the change in the physical coefficient of the physical model 34, which has been changed by the physical coefficient change unit 38. The information regarding the change in the physical coefficient is quantitative information.

In step S24, the deterioration state analysis unit 40 analyzes the deterioration state of the semiconductor manufacturing apparatus 10 in operation, based on the change in the physical coefficient. The deterioration state analysis unit 40 may analyze the deterioration state of the semiconductor manufacturing apparatus 10 in operation, based on a tendency of the change in the physical coefficient. The deterioration state of the semiconductor manufacturing apparatus 10 in operation corresponds to, for example, the tendency of the change in the physical coefficient.

The deterioration state analysis unit 40 may analyze, for example, from the tendency of the change in physical coefficient, the deterioration state of the semiconductor manufacturing apparatus 10 in operation after a predetermined period of time, or may analyze a progress of the deterioration state after a lapse of a predetermined period of time from the present.

In step S26, the deterioration state output unit 52 outputs the information regarding the deterioration state of the semiconductor manufacturing apparatus 10, which is analyzed by the deterioration state analysis unit 40. For example, the deterioration state output unit 52 transmits the information regarding the deterioration state of the semiconductor manufacturing apparatus 10, analyzed by the deterioration state analysis unit 40, to the operator terminal 18 to notify the operator of the information.

### <<Prediction>>

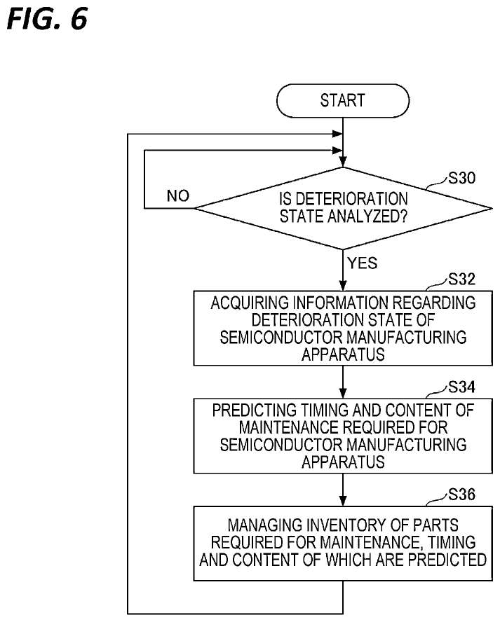

The semiconductor manufacturing system 1 according to the embodiment predicts a timing and a content of maintenance, as illustrated in FIG. 6, for example, based on the deterioration state of the semiconductor manufacturing apparatus 10 in operation, analyzed by the deterioration state analysis unit 40. FIG. 6 is a flowchart illustrating prediction of the semiconductor manufacturing system 1 according to the embodiment.

In step S30, when the deterioration state of the semiconductor manufacturing apparatus 10 in operation is analyzed by the deterioration state analysis unit 40, the autonomous control controller 14 performs processings of steps S32 to S36.

In step S32, the prediction unit 44 acquires the information regarding the deterioration state of the semiconductor manufacturing apparatus 10, analyzed by the deterioration state analysis unit 40. In step S34, the deterioration state analysis unit 40 predicts the timing and the content of maintenance required for the semiconductor manufacturing apparatus 10, based on the information regarding the deterioration state of the semiconductor manufacturing apparatus 10 in operation.

For example, the prediction unit 44 may set a threshold value for the deterioration state of the semiconductor manufacturing apparatus 10 that requires maintenance, for each maintenance content, and may predict the timing and the content of maintenance required for the semiconductor manufacturing apparatus 10, based on the information regarding the analyzed deterioration state of the semiconductor manufacturing apparatus 10.

In step S36, the inventory management unit 50 manages the inventory of parts required for maintenance, the timing and the content of which has been predicted by the prediction unit 44. For example, the inventory management unit 50 specifies parts required for maintenance for which the prediction unit 44 has predicted the timing and the content, and manages the inventory such that necessary parts are present in inventory at the timing of maintenance. The inventory management unit 50 may perform an automatic ordering of parts in accordance with the timing of maintenance by being linked to, for example, a parts purchase/management server disclosed in Japanese Patent Application Laid-Open Publication No. 2022-102821, which is an example of a purchasing system.

### <<Process Parameter Adjustment>>

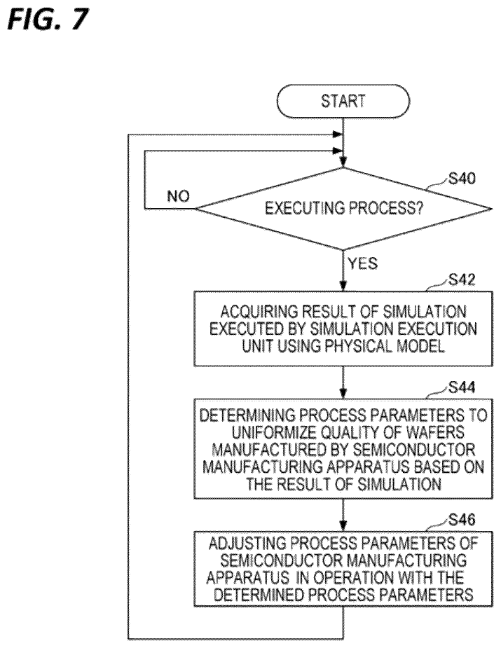

The semiconductor manufacturing system 1 according to the embodiment adjusts the process parameters of the semiconductor manufacturing apparatus 10 in operation, for example, as illustrated in FIG. 7, by using the physical model 34 whose physical coefficient has been changed by data assimilation. FIG. 7 is a flowchart illustrating process parameter adjustment of the semiconductor manufacturing system 1 according to the embodiment.

In step S40, when the semiconductor manufacturing apparatus 10 executes a process, the autonomous control controller 14 performs processings of steps S42 to S46.

In step S42, the adjustment unit 42 acquires a result of a simulation of a process state, which is being executed in the semiconductor manufacturing apparatus 10 by the simulation execution unit 32. In step S44, the adjustment unit 42 determines process parameters of operating conditions of the semiconductor manufacturing apparatus 10 based on the acquired result of the simulation, in order to uniformize the quality of wafers manufactured by the semiconductor manufacturing apparatus 10.

For example, the adjustment unit 42 determines process parameters such that a process state, such as a prediction temperature in the processing container of the semiconductor manufacturing apparatus 10, becomes constant and the quality of the wafers manufactured by the semiconductor manufacturing apparatus 10 becomes uniform.

In step S46, the adjustment unit 42 adjusts the process parameters of the semiconductor manufacturing apparatus 10 in operation, with the determined process parameters. By the processing of the process parameter adjustment of FIG. 7, the semiconductor manufacturing system 1 according to the embodiment may uniformize the quality of wafers that have been manufactured.

### <Summary>

For example, the semiconductor manufacturing apparatus 10 is developed and delivered to a customer side's manufacturing factory 2. The developed and delivered semiconductor manufacturing apparatus 10 is tested for whether there is a defect before delivery to the customer side's manufacturing factory 2. For the development, numerous processes such as planning, requirements analysis, functional design, structural design, detailed design, coding, a unit test, a combination test, a function test, a practical test, and a shipment decision meeting are performed until shipment. However, even when numerous processes are performed until shipment, it is not possible to guarantee that the semiconductor manufacturing apparatus 10 delivered to the customer side's manufacturing factory 2 will operate normally in the customer side's manufacturing factory 2 due to a difference in the environments of the customer side's manufacturing factory 2.

Therefore, the semiconductor manufacturing system 1 according to the embodiment executes the simulation of the process state under the same operating conditions as those of the semiconductor manufacturing apparatus 10 in operation, using the physical model 34 whose data assimilation with the semiconductor manufacturing apparatus 10 has been performed as a digital twin, after the semiconductor manufacturing apparatus 10 is delivered to the customer side's manufacturing factory 2.

The semiconductor manufacturing system 1 according to the embodiment changes the physical coefficient of the physical model such that the output value of the physical model 34 approximates to a corresponding output value of the semiconductor manufacturing apparatus 10, and analyzes the deterioration state of the semiconductor manufacturing apparatus 10 in operation, based on the change in the physical coefficients. The semiconductor manufacturing apparatus 10 in operation whose deterioration state is analyzed is a semiconductor manufacturing apparatus 10 immediately after delivery to the customer side's manufacturing factory 2 and may be a semiconductor manufacturing apparatus 10 in operation in the customer side's manufacturing factory 2.

The semiconductor manufacturing system 1 according to the embodiment may implement an autonomous digital twin system that predicts the timing and the content of failure of the semiconductor manufacturing apparatus 10 and predicts the timing and the content of maintenance of the semiconductor manufacturing apparatus 10 in the customer side's manufacturing factory 2 from the analyzed deterioration state of the semiconductor manufacturing apparatus 10.

With the autonomous digital twin system that predicts the timing and the content of failure of the semiconductor manufacturing apparatus 10 and predicts the timing and the content of maintenance of the semiconductor manufacturing apparatus 10 in the customer side's manufacturing factory 2, from the analyzed deterioration state of the semiconductor manufacturing apparatus 10, it is possible to autonomously improve reliability, performance, and maintainability.

In response to a limitation that it is difficult to apply the physical model 34 to the simulation of the process state of the semiconductor manufacturing apparatus 10, the semiconductor manufacturing system 1 according to the embodiment may facilitate the application of the physical model 34 by performing data assimilation with the semiconductor manufacturing apparatus 10 in operation through the digital twin.

The semiconductor manufacturing system 1 according to the embodiment, after a disorder occurs in the semiconductor manufacturing apparatus 10 in operation, changes the physical coefficient by the physical coefficient change unit 38 and learns a relationship between the change in the physical coefficient and the disorder (deterioration state) occurring in the semiconductor manufacturing apparatus 10, which may be used for advance detection of the disorder and prevention of the disorder. The semiconductor manufacturing system 1 according to the embodiment may recover the deterioration state of the semiconductor manufacturing apparatus 10 through maintenance, or deal with determination of a deterioration state that worsens over a long period of time even after maintenance, and the lifespan of parts through a future prediction.

### <Implementation Image>

Hereinafter, an example of optimization for each cleaning process will be described as an implementation image of the semiconductor manufacturing system 1 according to the embodiment. For example, according to a type of a process in which dry cleaning is performed, there is a semiconductor manufacturing apparatus 10 that performs dry cleaning once every three times.

In the semiconductor manufacturing apparatus 10 in operation, which performs dry cleaning once every three times, first, second, and third processes after the dry cleaning are performed consecutively with a starting from a thin film. Thus, a film thickness changes greatly due to a change in conditions.

In the semiconductor manufacturing system 1 according to the embodiment, whether the optimized process parameters are correct or not may be confirmed by performing re-simulation with previously optimized process parameters. Thus, it is possible to confirm whether the optimization is appropriate and how effective it is, and the process parameters may be applied by adjusting operating conditions using a digital twin system.

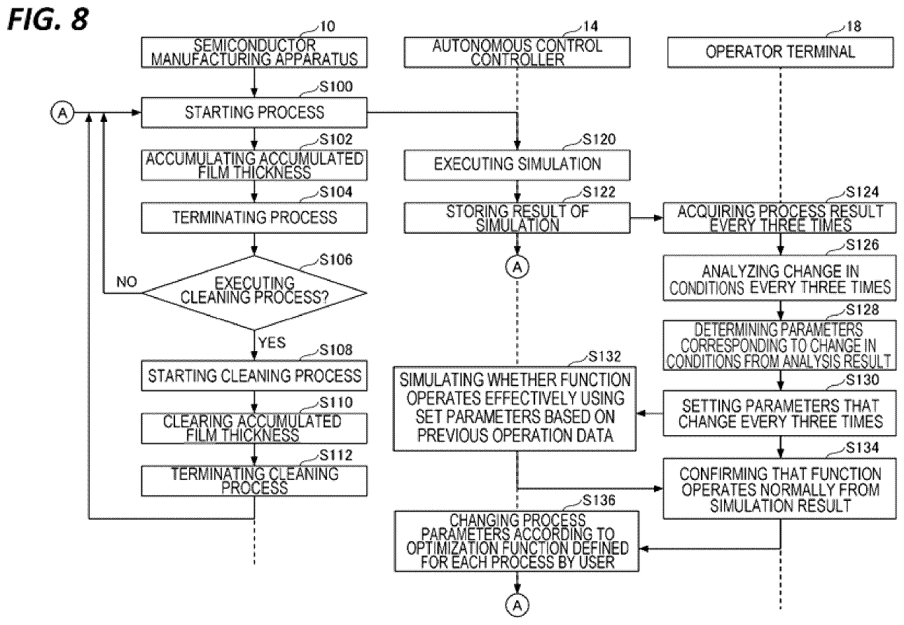

FIG. 8 is a flowchart illustrating optimization for each cleaning process of the semiconductor manufacturing system 1 according to the embodiment.

In step S100, the semiconductor manufacturing apparatus 10 starts a process. In step S102, the semiconductor manufacturing apparatus 10 accumulates an accumulated film thickness. In step S104, the semiconductor manufacturing apparatus 10 terminates the process.

In step S106, the semiconductor manufacturing apparatus 10 determines whether the number of times to execute the cleaning process has been reached. For example, the semiconductor manufacturing apparatus 10 performs determination to execute the cleaning process every three times the process is executed. When the number of times to execute the cleaning process has not been reached, the semiconductor manufacturing apparatus 10 returns to the processing of step S100. When the number of times to execute the cleaning process has been reached, the semiconductor manufacturing apparatus 10 proceeds to the processing of step S108.

In step S108, the semiconductor manufacturing apparatus 10 starts the cleaning process to execute dry cleaning. In step S110, the semiconductor manufacturing apparatus 10 clears an accumulated film pressure accumulated in step S102. In step S112, the semiconductor manufacturing apparatus 10 terminates the cleaning process and returns to the processing of step S100.

When the semiconductor manufacturing apparatus 10 starts the process in step S100, the autonomous control controller 14 performs a processing in step S120. In step S120, the autonomous control controller 14 sets the operating conditions of the physical model 34 of the semiconductor manufacturing apparatus 10 to the same conditions as the operating conditions of the semiconductor manufacturing apparatus 10 and executes a simulation of the process simultaneously with the process of the semiconductor manufacturing apparatus 10.

In step S122, the autonomous control controller 14 stores a result of the simulation. In step S124, the operator terminal 18 acquires a process result every three times. In step S126, the operator terminal 18 analyzes a change in conditions every three times. In step S128, the operator terminal 18 determines a parameter corresponding to the change in the conditions from an analysis result. In step S130, the operator terminal 18 sets a parameter such as temperature, humidity, or gas that changes every three times.

In step S132, the autonomous control controller 14 simulates whether functions operate effectively using the set parameter based on previous operation data. In step S134, the operator terminal 18 confirms to an operator, that functions operate normally from the result of simulation.

In step S136, the autonomous control controller 14 changes the process parameter according to an optimization function defined by the operator for each of the three processes, and returns to the processing of step S100.

With the semiconductor manufacturing system 1 according to the embodiment, it is possible to provide a simulation technology using the physical model 34 corresponding to the deterioration state of the semiconductor manufacturing apparatus 10. In addition, with the semiconductor manufacturing system 1 according to the embodiment, it is possible to provide a technology for analyzing and outputting the deterioration state of the semiconductor manufacturing apparatus 10 in real time.

According to the present disclosure, it is possible to provide a simulation technology using a physical model corresponding to a deterioration state of a semiconductor manufacturing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
a simulation execution circuitry configured to execute a simulation of a process state, which is being executed in a semiconductor manufacturing apparatus, using a physical model of the semiconductor manufacturing apparatus by setting operating conditions of the physical model to same conditions as those of the semiconductor manufacturing apparatus;
a physical coefficient change circuitry configured to change a physical coefficient of the physical model such that an output value of the physical model approximates to a corresponding output value of the semiconductor manufacturing apparatus;
a deterioration state analysis circuitry configured to analyze a deterioration state of the semiconductor manufacturing apparatus, based on a change in the physical coefficient; and
a deterioration state output circuitry configured to output information regarding the deterioration state of the semiconductor manufacturing apparatus analyzed by the deterioration state analysis circuitry.

2. The information processing apparatus according to claim 1, wherein the simulation execution circuitry executes the simulation of the process state, which is being executed in the semiconductor manufacturing apparatus, using the physical model whose physical coefficient has been changed by the physical coefficient change circuitry.

3. The information processing apparatus according to claim 1, further comprising:
a prediction circuitry configured to predict a timing and a content of maintenance required for the semiconductor manufacturing apparatus, based on the deterioration state of the semiconductor manufacturing apparatus analyzed by the deterioration state analysis circuitry.

4. The information processing apparatus according to claim 3, further comprising:
an inventory management circuitry configured to manage an inventory of parts required for the maintenance, the timing and the content of which are predicted by the prediction circuitry.

5. The information processing apparatus according to claim 1, further comprising:
an adjustment circuitry configured to adjust process parameters of the operating conditions of the semiconductor manufacturing apparatus to uniformize a quality of wafers manufactured by the semiconductor manufacturing apparatus, based on a result of the simulation of the process state, which is being executed in the semiconductor manufacturing apparatus, executed using the physical model.

6. The information processing apparatus according to claim 1, wherein the physical coefficient change circuitry changes the physical coefficient of the physical model such that the output value of the physical model approximates to an output value of the semiconductor manufacturing apparatus or another semiconductor manufacturing apparatus, which is accumulated through operation.

7. The information processing apparatus according to claim 1, wherein the deterioration state of the semiconductor manufacturing apparatus corresponds to a tendency of the change in the physical coefficient.

8. An information processing method comprising:
providing an information processing apparatus configured to execute a simulation of a process state, which is being executed in a semiconductor manufacturing apparatus, using a physical model of the semiconductor manufacturing apparatus,
executing the simulation by setting operating conditions of the physical model to same conditions as those of the semiconductor manufacturing apparatus;
changing a physical coefficient of the physical model such that an output value of the physical model approximates to a corresponding output value of the semiconductor manufacturing apparatus;
analyzing a deterioration state of the semiconductor manufacturing apparatus based on a change in the physical coefficient; and
outputting information regarding the deterioration state of the semiconductor manufacturing apparatus analyzed in the analyzing.

9. A semiconductor manufacturing system comprising:
a semiconductor manufacturing apparatus; and
an information processing apparatus,
wherein the information processing device includes,
a simulation execution circuitry configured to execute a simulation of a process state, which is being executed in a semiconductor manufacturing apparatus, using a physical model of the semiconductor manufacturing apparatus by setting operating conditions of the physical model to same conditions as those of the semiconductor manufacturing apparatus;
a physical coefficient change circuitry configured to change a physical coefficient of the physical model such that an output value of the physical model approximates to a corresponding output value of the semiconductor manufacturing apparatus;
a deterioration state analysis circuitry configured to analyze a deterioration state of the semiconductor manufacturing apparatus, based on a change in the physical coefficient; and
a deterioration state output circuitry configured to output information regarding the deterioration state of the semiconductor manufacturing apparatus analyzed by the deterioration state analysis circuitry.
